(19) United States
(12) Patent Application Publication
(10) Pub. No.: US 2026/0351440 A1
(43) Pub. Date: Nov. 5, 2026

(54) METHOD FOR TRANSPORTING AND ARRANGING ELECTRONIC COMPONENTS USING OPTICAL TRAPS

(71) Applicant: THE TRUSTEES OF PRINCETON UNIVERSITY, Princeton, NJ (US)

(72) Inventor: Daniel B. Shaw, West Grove, PA (US)

(73) Assignee: THE TRUSTEES OF PRINCETON UNIVERSITY, Princeton, NJ (US)

(21) Appl. No.: 19/125,540

(22) PCT Filed: Oct. 24, 2023
(86) PCT No.: PCT/US2023/035784

§ 371 Date: Apr. 29, 2025

Related U.S. Application Data
(60) Provisional application No. 63/381,557, filed on Oct. 29, 2022.
(60) Provisional application No. 63/487,243, filed on Feb. 27, 2023.

(51) Int. Cl. G21K 1/30; H10H 29/03

(52) U.S. Cl. CPC G21K 1/30; H10H 29/03

(57) ABSTRACT

Disclosed is a technique for transporting and arranging electronic components, using an optical system utilizing a laser beam to produce an optical trap in a fluid near a target site of a backplate, where a primary optical axis of the laser beam is perpendicular to the backplate and defines a longitudinal axis with an upwards direction pointing away from the backplate into the fluid, where a transverse direction lies in a plane parallel to the backplate. The technique may include providing a fluid comprising an electronic element mixed with a transport medium, the transport medium having a lower refractive index than the electronic element. The technique may include applying the fluid to a backplate surface as a film. The technique may include orienting and/or positioning the electronic element relative to the backplate by producing an optical trap near the target site. The element may then be attached to the backplate.

### CROSS-REFERENCE TO RELATED APPLICATIONS

The present application claims priority to U.S. Provisional Patent Application Nos. 63/487,243, filed Feb. 27, 2023, and 63/381,557, filed Oct. 29, 2022, the contents of each are incorporated by reference herein in its entirety.

### TECHNICAL FIELD

The present disclosure is drawn to the field of manufacturing, and specifically, for a method for using optical traps to manufacture electronic components.

### BACKGROUND

This section is intended to introduce the reader to various aspects of art, which may be related to various aspects of the present invention that are described and/or claimed below. This discussion is believed to be helpful in providing the reader with background information to facilitate a better understanding of the various aspects of the present invention. Accordingly, it should be understood that these statements are to be read in this light, and not as admissions of prior art.

In the field of electronics manufacturing, current methods of arranging small components, such as ‘pick and place’ make trade-offs between speed and accuracy, becoming prohibitively costly as element size decreases.

### BRIEF SUMMARY

Various deficiencies in the prior art are addressed below by the disclosed compositions of matter and techniques.

In various aspects, a method for transporting and arranging electronic components may be provided. The method may involve an optical system that utilizes a laser beam to produce an optical trap in a fluid near a target site of a backplate. A primary optical axis of the laser beam may be perpendicular to a surface of the backplate and may define a longitudinal axis with an upwards direction pointing away from the backplate surface into the fluid. A transverse direction may lie in a plane parallel to the backplate surface.

The method may include providing a fluid (such as, e.g., a suspension or emulsion) comprising an electronic element (such as, e.g., a semiconducting or superconducting electronic element) mixed with a transport medium (which may be, e.g., a liquid or gel). In some embodiments, the electronic element may be, e.g., a microLED. The electronic element may be coupled to a particle. The transport medium may have a lower refractive index than the electronic element. The transport medium may include, e.g., water, a peroxide (such as, e.g., hydrogen peroxide), or an alcohol (such as, e.g., a C2-C5 monoalcohol). The transport medium may include a surfactant (such as, e.g., an anionic surfactant, such as sodium dodecyl sulphate, or a non-ionic surfactant, such as 2-[4-(2,4,4-trimethylpentan-2-yl)phenoxy]ethanol). The transport medium may include an oil (such as, e.g., a volatile hydrocarbon oil, such as isododecane).

In some embodiments, the transport medium may include a droplet, such as, e.g., a dispersed phase in an emulsion. The electronic element may be disposed within a droplet.

The method may include applying the fluid to a surface of a backplate as a film. The backplate, such as the surface of the backplate, may include one or more micro-or nano-scale features configured to focus the laser beam and produce the optical trap.

The method may include orienting and/or positioning the electronic element relative to the backplate by producing an optical trap near the target site. The element may then be attached to the backplate.

The method may include transferring the electronic element from the backplate to a second substrate. The method may include flowing the fluid in a transverse direction. The method may include moving the optical trap. The method may include using one or more additional laser beams to create one or more additional optical traps. The method may include imaging the optical trap through at least one objective lens which focuses the laser beam to observe the electronic element in the optical trap. The method may include using the optical trap to impart a torque on the electronic element. The method may include adjusting a distance between the electronic element and the backplate by raising or lowering the optical trap relative to the backplate. The method may include removing the transport medium via evaporation. The method may include flushing the target site using either a secondary fluid with a lower concentration of electronic element than in the transport medium, or a secondary fluid that is free of electronic elements. The method may include incorporating the electronic element, attached to the backplate or to a second substrate, into an electronic device being manufactured.

In some embodiments, providing the fluid may include forming the fluid by mixing the electronic element with the transport medium. In some embodiments, the laser beam may be oriented such that it produces the optical trap before hitting the backplate. In some embodiments, the laser beam may be oriented such that it passes through the backplate before it produces the optical trap.

In various aspects, a system for transporting and arranging electronic components may be provided. The system may include a backplate. The system may include a fluid disposed on the backplate, the fluid comprising an electronic element mixed with a transport medium. The system may include a laser source configured to generate a laser beam. The laser beam may be directed to a target site on the backplate. The laser beam may be configured to generate an optical trap in the fluid near the target site.

### BRIEF DESCRIPTION OF FIGURES

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1 is a flowchart of a method.

FIG. 2 is an illustration of a system.

FIG. 3 is an illustration of a side-view of a system manipulating multiple electrical elements with optical traps.

FIGS. 4A-4D are illustrations schematically showing capture, positioning, and orienting a single electrical element in an optical trap, before moving the element to the site where it is desired to be placed.

FIG. 5 is an illustration of a top down view (along the optical axis) of a system, showing an array of optical traps and target sites.

FIG. 6 is an illustration of a portion of a system with a diffractive optical element and an objective lens.

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION

The following description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for illustrative purposes to aid the reader in understanding the principles of the invention and the concepts contributed by the inventor(s) to furthering the art and are to be construed as being without limitation to such specifically recited examples and conditions. Additionally, the term, “or,” as used herein, refers to a non-exclusive or, unless otherwise indicated (e.g., “or else” or “or in the alternative”). Also, the various embodiments described herein are not necessarily mutually exclusive, as some embodiments can be combined with one or more other embodiments to form new embodiments.

The numerous innovative teachings of the present application will be described with particular reference to the presently preferred exemplary embodiments. However, it should be understood that this class of embodiments provides only a few examples of the many advantageous uses of the innovative teachings herein. In general, statements made in the specification of the present application do not necessarily limit any of the various claimed inventions. Moreover, some statements may apply to some inventive features but not to others. Those skilled in the art and informed by the teachings herein will realize that the invention is also applicable to various other technical areas or embodiments.

As used herein, articles such as “a” and “an” when used in a claim, are understood to include one, or one or more, of what is claimed or described.

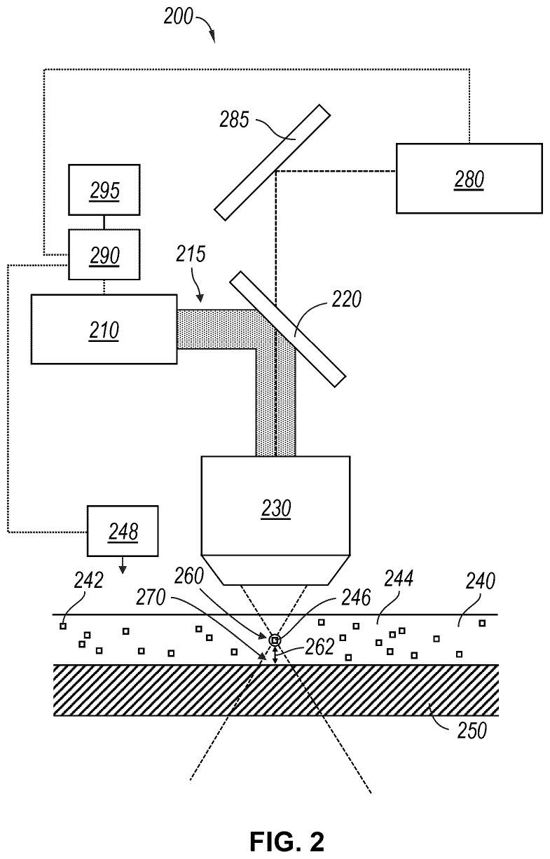

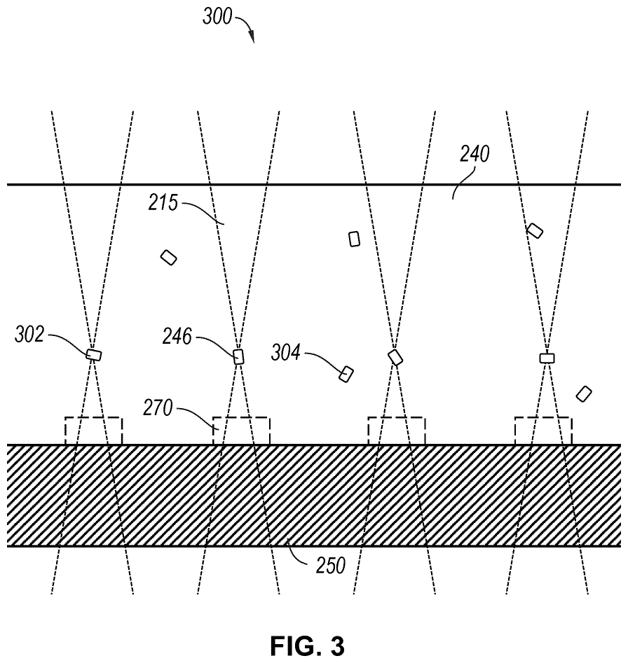

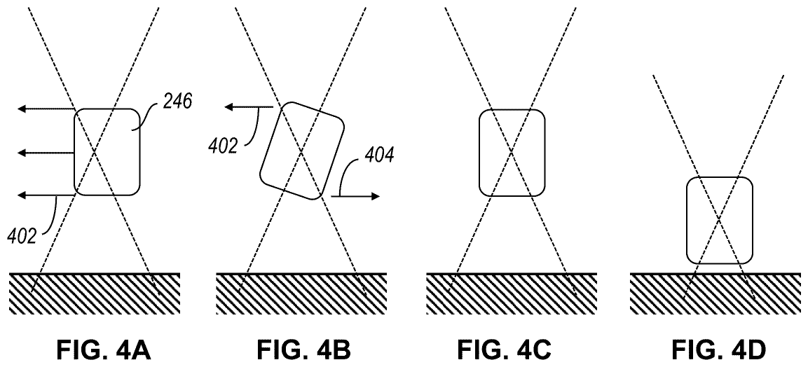

The present disclosure utilizes optical tweezers. Optical tweezers use concentrated light to apply forces and torques to particles in a fluid (see, e.g., FIGS. 2 and 3). From cells and biomolecules to Si beads and nanoparticles, a variety of microscopic particles-ranging in size from about 1 nanometer to about 100 micrometers-can be manipulated. A single setup can produce ordered patterns of traps (each controlled individually) to which particles are attracted (see, e.g., FIGS. 4A-4D).

The present disclosure uses fluid flow to transport electrical elements to near their desired final sites and then using arrays of optical traps to precisely orient and position each element.

Optical tweezers (as they are commonly defined) were first developed in 1986 by Ashkin et al, and the technique has subsequently become a common tool to control small particles that are not easily manipulated by mechanical contact. From a trapped particle's perspective, the only requisite of a trap is the convergence of a laser beam to a diffraction-limited spot in fluid surrounding the particle. See, e.g., FIG. 2. The focused light produces a 3-dimensional intensity gradient. The trapped particle experiences forces and torques due to momentum conservation by altering the direction of the laser light. Optical tweezers require relatively little power to produce the required forces; for a 10 mW focused laser beam, the transverse (perpendicular to the optical axis) force per unit of displacement is on the order of 1 fN/m.

In contrast to many of the common applications of optical tweezers that focus on controlling delicate materials, this disclosure additionally leverages the systematic ease by which a large number of particles can be arranged into orderly patterns with each particle controlled individually.

Electronics manufacturing is a high-opportunity application of this capability which has thus far not been proposed; as electronic elements shrink in size, their assembly by mechanical methods has become increasingly difficult, time consuming, and costly. Micro LED (mLED) elements, for example, have been developed and are expected to be widely used in electronic screens, but the manufacturing methods by which mLED screens are assembled remain ineffective and costly due primarily to the small size of the elements; mLEDs tend to range from 5 to 100 micrometers, and it can be both technically challenging and cost-prohibitive to assemble devices in that size range using conventional techniques.

In various aspects, a method for transporting and arranging electronic components may be provided. The method may involve an optical system that utilizes a laser beam to produce an optical trap in a fluid near a target site of a backplate.

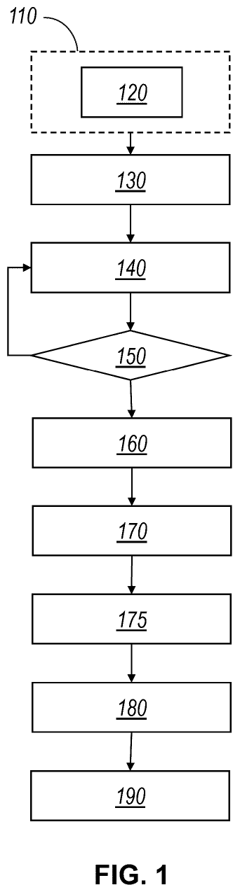

Referring to FIG. 1, the method may include providing 110 a fluid (such as, e.g., a suspension or emulsion) comprising an electronic element (such as, e.g., a semiconducting or superconducting electronic element) mixed with a transport medium (which may be, e.g., a liquid or gel).

In some embodiments, the electronic element may be, e.g., a microLED. The electronic element may be coupled to a particle.

The transport medium may have a lower refractive index than the electronic element. Tightly focusing a laser beam to a diffraction-limited spot in a fluid will create a ‘trap’ to which particles with a higher refractive index than the fluid medium are attracted in three dimensions. In some embodiments, the refractive index of the transport medium may be no at least 1.5. In some embodiments, the refractive index of the transport medium may be no more than 5. In some embodiments, the refractive index of the transport medium may be no more than 4. In some embodiments, the refractive index of the transport medium may be no more than 3. In some embodiments, the refractive index of the transport medium may be no more than 2.5 In some embodiments, the refractive index of the transport medium may be no more than 2. In some embodiments, the refractive index of the transport medium may be no more than 1.9. In some embodiments, the refractive index of the transport medium may be no more than 1.8. In some embodiments, the refractive index of the transport medium may be no more than 1.7. In some embodiments, the refractive index of the transport medium may be no more than 1.6. In some embodiments, the refractive index of the transport medium may be no more than 1.5. In some embodiments, the refractive index of the transport medium may be no more than 1.45. In some embodiments, the refractive index of the transport medium may be no more than 1.4. In some embodiments, the refractive index of the transport medium may be no more than 1.35.

The transport medium may include, e.g., water, a peroxide (such as, e.g., hydrogen peroxide), or an alcohol (such as, e.g., a C2-C5 monoalcohol). The transport medium may include a surfactant (such as, e.g., an anionic surfactant, such as sodium dodecyl sulphate, or a non-ionic surfactant, such as 2-[4-(2,4,4-trimethylpentan-2-yl)phenoxy]ethanol). The transport medium may include an oil (such as, e.g., a volatile hydrocarbon oil, such as isododecane).

In some embodiments, the transport medium may include a droplet, such as, e.g., a dispersed phase in an emulsion. The electronic element may be disposed within a droplet.

In some embodiments, providing 110 the fluid may include forming 120 the fluid by mixing the electronic element with the transport medium.

The method may include applying 130 the fluid to a surface of a backplate as a film. The backplate, such as the surface of the backplate, may include one or more micro- or nano-scale features configured to focus the laser beam and produce the optical trap. Such features are well-known in the art.

In some embodiments, the backplate to which the elements will be attached may be the final surface that the elements are bonded to in the device.

In some embodiments, the backplate may be a transfer substrate. The transfer substrate may be specifically designed to facilitate arrangement, flow, placement, securement, and orientation of the elements being manipulated by the optical traps. The design choices can include but are not limited to the material, surface characteristics (patterning, roughness, three-dimensional features), size, and optical properties. The transfer substrate is not required to be included in the final manufactured product, but it could be.

The method may include trapping the electronic element relative to the backplate by producing 140 an optical trap in the fluid near a target site. The optical trap can be used to both trap and orient and the elements. In some embodiments, the method may include using the optical trap to impart a torque on the electronic element. Techniques for optically imparting torque are well understood in the art. In some embodiments, this may include using one or more additional laser beams to create one or more additional optical traps.

In some embodiments, the laser beam may be oriented such that it produces the optical trap before hitting the backplate. In some embodiments, the laser beam may be oriented such that it passes through the backplate before it produces the optical trap.

The method may include verifying 150 the elements are in traps. In some embodiments, this may be done by imaging the optical trap through at least one objective lens (which may be a same lens that focuses the laser beam) to observe the electronic element in the optical trap. In some embodiments, verifying may include flowing the fluid in a transverse direction.

This producing 140 and verifying 150 may occur until an electronic element is verified as being in a given trap.

The method may include moving 160 the optical trap(s). This may occur after verifying one or more electronic element(s) are in the trap(s). This may include adjusting a distance between the electronic element and the backplate by raising or lowering the optical trap relative to the backplate. The optical trap may be used to push and/or pull the electronic element into position on the backplate.

The method may then include attaching 170 the element(s) to the backplate (or allowing the elements(s) to attach to the backplate). The attachment may occur due to, e.g., intermolecular forces, such as van der Waals forces or other mechanisms. This may include, e.g., physical barriers or restraints (e.g., a depression in the backplate with sidewalls preventing the electronic element from sliding out of the depression)

The method may then include removing 175 the transport medium. In some embodiments, this may include removing at least some of the transport medium via evaporation. In some embodiments, this may include flowing the fluid in a transverse direction with a flowrate small enough to not dislodge the positioned elements. The actual flow rate will be a strong function of the geometry of the electronic element and how securely it has been attached to the backplate.

In some embodiments, this may include flushing the backplate with a secondary fluid, the secondary fluid being a liquid or liquid-like medium, to remove any electrical elements not attached to the backplate. As used herein, the term “liquid-like medium” is intended to refer to fluids that behave like a liquid; for example, there are some complex fluids that do not behave like a fluid. The secondary fluid preferably has a lower concentration of electrical elements, or no electrical elements at all as compared to the first fluid being flushed away. In some embodiments, the secondary fluid may have a lower viscosity than the primary fluid. In some embodiments, the secondary fluid may have a greater volatility than the primary fluid. The term “volatility” means the relative tendency of a liquid to vaporize, and can be measured by any suitable physical property, including vapor pressure or distillation temperature.

The method may include transferring 180 the electronic element from the backplate to a second substrate. In such embodiments, the backplate may be a transfer substrate as disclosed herein, configured to allow the elements to be transferred from a surface of the transfer substrate to a surface for the second substrate. Such techniques are well understood in the art.

In some embodiments, the backplate or second substrate may be used as a component in a separate device. As such, it is understood that the method may include incorporating 190 the electronic element, attached to the backplate or to a second substrate, into an electronic device being manufactured.

As will be understood, the method is not restricted to having the electronic element transferred from the backplate to a single additional substrate. Any number of intermediate surfaces or materials between the one which the elements are arranged (e.g., the backplate described above) and their final incarnation in a device being manufactured (or a subsequent component which will be incorporated into a device being manufactured) may be utilized.

In various aspects, a system for transporting and arranging electronic components may be provided, that preferably is utilizes as per the method disclosed herein.

Referring to FIG. 2, the system 200 may include a backplate 250. The system may include a fluid 240 disposed on the backplate. As disclosed herein, the fluid may be comprising an electronic element 242 mixed with a transport medium 244. The fluid may be provided from a fluid source 248, which may include, e.g., a storage container, a syringe, a metering device, and/or any other known means for storing the fluid and/or causing fluid to flow from storage to form the film as disclosed herein without destroying the electrical elements therein.

The system may include at least one laser source 210 configured to generate one or more laser beams 215. The laser beam(s) may be directed (e.g., via one or more mirrors 220 and/or lenses, which preferably includes an objective lens 230) to a target site 270 on the backplate. The laser beam may be configured to generate an optical trap 260 in the fluid 240 near the target site (e.g., which may be at a distance 262 (d) from the backplate, where d>0 nm. A trapped electrical element 246 is shown in the optical trap.

The system may include a camera 280, which may be configured to receive light along an optical path from the optical trap, which may be directed using one or more mirrors 285, lens, etc. As used herein, the term “camera” may refer to any device or sensor capable of converting an optical image into electrical signals, such as a charge coupled device (CCD) or complementary metal oxide semiconductor (CMOS) sensor.

The system may include one or more processors 290, which may be coupled to a non-transitory computer readable storage device 295. The storage device may include instructions that, when executed by the processor(s), the processor(s), collectively, perform various steps. Those steps may include an embodiment of a method as disclosed herein.

In some embodiments, after causing the fluid to be provided to the backplate and form an optical trap, the processor(s) may be configured to receive an image from a camera of the optical trap, and determine if an electrical element is present in the optical trap by performing image processing of the image as understood by those of skill in the art. If an element is present, the processor(s) may be configured to position and/or orient the electrical element as required. If an element is not present, the processor(s) may be configured to adjust a position of the trap, adjust a flow condition in the film, etc., and then repeat the process of capturing another image and determining if an electrical element is present.

Referring to FIG. 3, in some embodiments, the method/system may utilize an array of laser beams 215. Creating arrays of beams enables the simultaneous manipulation of multiple electrical elements. As seen here, multiple elements may be trapped (see, e.g., trapped electrical elements 246, 302), while other elements 304 remain outside the optical traps within the fluid 240. Once trapped, multiple elements may then be moved into their target locations 270 at or near the surface of the backplate 250. The trapped electrical elements may be oriented so as to have a same orientation. As shown, the trapped electrical elements may be oriented so as to have different orientations (see, e.g., the orientation of first trapped electrical element 246 as compared to the orientation of second trapped electrical element 302)

Referring to FIGS. 4A-4D, an illustration is shown of an example process for the capture and orientation of a single element in an optical trap and how the trap can be used to position it at the site where it is desired to be placed. Referring to FIG. 4A, at the start, the trapped electrical element 246 is not at the equilibrium position of the trap, but it is close enough that it experiences a force (here a force 402 to the left) pulling it towards an equilibrium position within the trap.

Referring to FIG. 4B, if the element is also not oriented correctly, it will experience a torque to orient it. This is shown as having a first force (here force 402 to the left) pulling a portion of the element (here, a top portion) in one direction, while a second force (here force 404 to the right) pulling an opposite portion of the element (here, a bottom portion) in an opposite direction.

Referring to FIG. 4C, once centered in the trap, the element resides in the stable equilibrium of the trap.

Referring to FIG. 4D, preferably after the element is in stable equilibrium of the trap, a trapped element can be translated to its desired site by slowly moving the position of the trap.

Note, the figures are not drawn to scale, and that the laser beam forming the trap does not pass through the electrical elements unaltered. Indeed, the laser beam's refraction and reflection are the very feature which enables their trapping behavior. The precise paths of each ray in the laser beam are nontrivial and often requires intensive calculations that depend on many variables including the fluid medium, the content and geometry of the particle, and the laser employed. As such, the beams are drawn to pass straight through the particle for simplicity of the drawings.

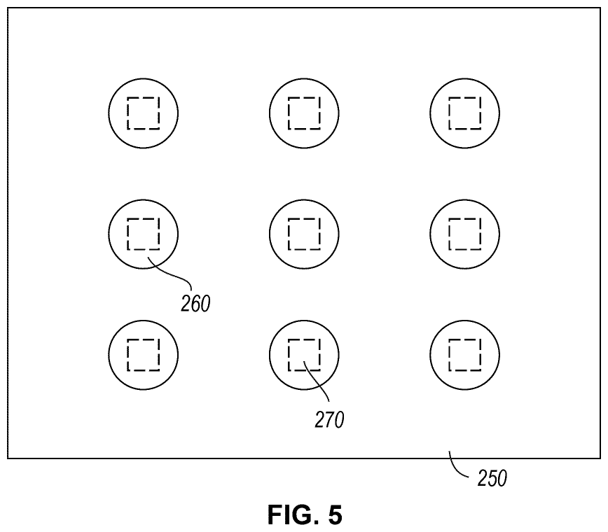

Referring to FIG. 5, a top-down view can be seen, where the backplate 250 is shown, with an array of optical traps 260 and desired sites for the optical elements 270. The shape and size of the arrays can be easily controlled by manipulation of one or more laser beams before the beam reaches the trap, as understood in the art. As such, large arrays of traps can be easily created from, e.g., a single beam.

The most commonly employed technique to alter the beam is the addition of diffractive optical elements (DOEs) in a plane conjugate to the objective back aperture which change just the phase of the light passing through it, to create arbitrary arrays. A device employing a DOE to create multiple optical traps is sometimes referred to as a holographic optical tweezer (HOT).

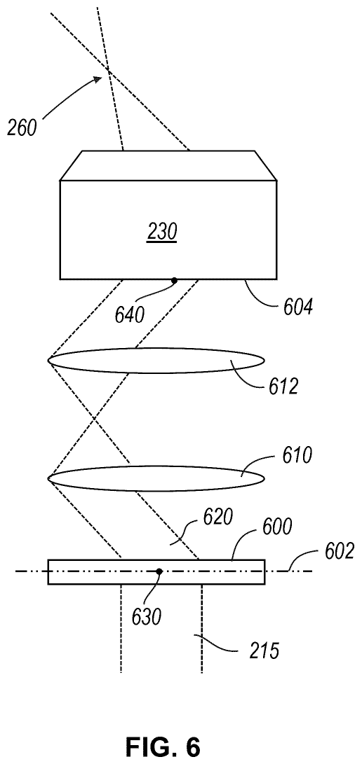

Referring to FIG. 6, arbitrary arrays of optical traps can be formed, when a diffractive optical element 600 is disposed substantially in a plane 602 conjugate to back aperture 604 of the objective lens 230. The laser beam 215 passes through the DOE, and then may pass through one or more additional lenses 610, 612 (which may form a telescope) before passing into the objective lens. The additional lenses 610, 612 may be used to establishes a point 630 which is optically conjugate to the center point 640

Note that only a single diffracted output beam 620 from the DOE is shown for clarity, but it should be understood that a plurality of such beams can be created by the diffractive optical element. The input light beam incident on the diffractive optical element may be split into a pattern of the output beams characteristic of the nature of the diffractive optical element, each of which may emanate from a point 630. Thus, the output beams will pass through point 640 as a consequence of the downstream optical elements described herein before.

The diffractive optical element is shown as being normal to the input light beam, but many other arrangements are possible. For example, the light beam may arrive at an oblique angle relative to the optic axis and not normal to the diffractive optical element.

As used herein, the term “diffractive optical element” refers to a device designated for influencing the beam profile of the incident light beam by altering the beam shape using optical diffraction. The diffractive optical element may include a structure which is designated for optically diffracting in incident light beam. Non-limiting examples of a diffractive optical element include an optical grating, a diffractive micro-or nano-structure, a Fresnel lens, or a metasurface. As used herein, the term “optical grating” refers to an optical element having a periodic structure, such as parallel ridges or grooves introduced into a transparent substrate, which is designed for diffracting an incident light beam depending on a width and a spacing of the diffractive structure of the optical grating. As used herein, the term “diffractive micro-or nano-structure” refers to an optical element comprising a plurality of micro-or nano-machined complex micro-or nano-scale protrusions and/or grooves. As further generally used, the term “Fresnel lens” refers to a composite compact lens which is, compared to a lens of conventional design, provided in a mass and/or volume reduced fashion, especially for allowing a construction of a lens having a large aperture and a short focal length. As further generally used, the term “metasurface” refers to an artificial substrate having a sub-wavelength thickness and being designed for modulating a behavior of the incident light beam through boundary conditions, wherein the metasurface can be either structured or unstructured with subwavelength-scaled patterns in at least one horizontal dimension.

Another possible method is to split the beam to create the effect of multiple individual traps all focused by the same objective lens.

Various modifications may be made to the systems, methods, apparatus, mechanisms, techniques and portions thereof described herein with respect to the various figures, such modifications being contemplated as being within the scope of the invention. For example, while a specific order of steps or arrangement of functional elements is presented in the various embodiments described herein, various other orders/arrangements of steps or functional elements may be utilized within the context of the various embodiments. Further, while modifications to embodiments may be discussed individually, various embodiments may use multiple modifications contemporaneously or in sequence, compound modifications and the like.

Although various embodiments which incorporate the teachings of the present invention have been shown and described in detail herein, those skilled in the art can readily devise many other varied embodiments that still incorporate these teachings. Thus, while the foregoing is directed to various embodiments of the present invention, other and further embodiments of the invention may be devised without departing from the basic scope thereof. As such, the appropriate scope of the invention is to be determined according to the claims.

What is claimed is:

1. A method for transporting and arranging electronic components, using an optical system utilizing a laser beam, where a primary optical axis of the laser beam is perpendicular to a backplate and defines a longitudinal axis with a direction pointing away from a surface of the backplate, where a transverse direction lies in a plane parallel to the surface of the backplate, the method comprising:
providing the fluid, where the fluid includes an electronic element mixed with a transport medium, the transport medium having a lower refractive index than the electronic element;
applying the fluid to the surface of the backplate as a film; and
arranging the electronic element relative to the backplate by producing an optical trap near a target site using the laser beam.

2. The method of claim 1, wherein providing the fluid includes forming the fluid by mixing the electronic element with the transport medium.

3. The method of claim 1, wherein the electronic element is coupled to a particle.

4. The method of claim 1, wherein the laser beam is oriented such that it produces the optical trap before hitting the backplate.

5. The method of claim 1, wherein the laser beam is oriented such that it passes through the backplate before it produces the optical trap.

6. The method of claim 1, further comprising transferring the electronic element from the backplate to a second substrate.

7. The method of claim 1, wherein the backplate comprises one or more micro-or nano-scale features configured to focus the laser beam and produce the optical trap.

8. The method of claim 1, wherein the transport medium is a liquid.

9. The method of claim 1, wherein the transport medium is a gel.

10. The method of claim 1, wherein the transport medium includes water, a peroxide, or an alcohol.

11. The method of claim 10, wherein the transport medium comprises a surfactant.

12. The method of claim 1, wherein the transport medium includes an oil.

13. The method of claim 1, wherein the transport medium comprises a droplet, and wherein the electronic element is disposed within a droplet.

14. The method of claim 1, wherein the electronic element is a superconducting electronic element.

15. The method of claim 1, wherein the electronic element is a semiconducting electronic element.

16. The method of claim 15, wherein the semiconducting electronic element is a microLED.

17. The method of claim 1, further comprising flowing the fluid in a transverse direction.

18. The method of claim 1, further comprising moving the optical trap.

19. The method of claim 1, further comprising using one or more additional laser beams to create one or more additional optical traps.

20. The method of claim 1, further comprising imaging the optical trap through at least one objective lens which focuses the laser beam to observe an electronic element in the optical trap.

21. The method of claim 1, further comprising using the optical trap to impart a torque on the electronic element.

22. The method of claim 1, further comprising adjusting a distance between the electronic element and the backplate by raising or lowering the optical trap relative to the backplate.

23. The method of claim 1, further comprising removing the transport medium via evaporation.

24. The method of claim 1, further comprising flushing the target site using either a secondary fluid with a lower concentration of electronic element than in the transport medium, or a secondary fluid that is free of electronic elements.

25. The method of claim 1, further comprising incorporating the electronic element, attached to the backplate or to a second substrate, into an electronic device being manufactured.

26. A system for transporting and arranging electronic components, comprising:
a backplate;
a fluid disposed on the backplate, the fluid comprising an electronic element mixed with a transport medium; and
a laser source configured to generate a laser beam, the laser beam being directed to a target site on the backplate, the laser beam configured to generate an optical trap in the fluid near the target site.
